(19) United States
(12) Patent Application Publication
(10) Pub. No.: US 2008/0212466 A1
(43) Pub. Date: Sep. 4, 2008

(54) APPARATUS, TRANSMISSION METHOD, AND TANGIBLE MACHINE-READABLE MEDIUM THEREOF FOR RELAYING A DATA SIGNAL IN A MILTI-HOP NETWORK

(75) Inventors: Chih-Chiang Hsieh, Jen-Wu Township (TW); Shiann-Tsong Sheu, Taipei (TW); Hua-Chiang Yin, Guei-Shan Township (TW); Youn-Tai Lee, Yung-Ho City (TW); Kan-chei Loa, Taipei (TW); Yung-Ting Lee, Taipei (TW); Yi-Hsueh Tsai, Ban-Chiao (TW); Frank Chee-Da Tsai, Taipei (TW); Heng-Iang Hsu, Taipei (TW)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: INSTITUTE FOR INFORMATION INDUSTRY, Taipei (TW)

(21) Appl. No.: 11/951,116

(22) Filed: Dec. 5, 2007

Related U.S. Application Data
(60) Provisional application No. 60/892,725, filed on Mar. 2, 2007.

(51) Int. Cl. G01R 31/08

(52) U.S. Cl. 370/229

(57) ABSTRACT

An apparatus, a transmission method, and a tangible machine-readable medium thereof for relaying a data signal in a multi-hop relay network are provided, wherein the multi-hop relay network comprising a plurality of relay stations. The apparatus comprises a storage module, a receiving module, and a transmission module. The storage module is configured to store a message of the multi-hop relay network, the message indicating a relation between the apparatus and the relay stations. The receiving module is configured to receive the data signal. The transmission module is configured to transmit the data signal and a first response signal according to the message in response to the data signal, wherein the first response signal relates to a correctness of the data signal.

This application claims the benefit of U.S. Provisional Application Ser. No. 60/892,725 filed on Mar. 2, 2007, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to an apparatus, a transmission method, and a tangible machine-readable medium for relaying a data signal. More specifically, the present invention relates to an apparatus, a transmission method, and a tangible machine-readable medium for relaying a data signal in multi-hop relay network.

2. Descriptions of the Related Art

The hybrid automatic request (HARQ) technique, adopted in the IEEE 802.16 standard, is an advanced data retransmission strategy, which allows performing possible data retransmissions directly at the physical layer instead of the media access control (MAC) layer and/or higher layers. Since the HARQ technique is able to achieve data retransmission without involving mechanisms at the higher layers, the delay caused by data retransmission is significantly reduced. However, the HARQ technique still has some defects in the relay of a multi-hop relay network, and the defects are going to be defined in the IEEE 802.16j standard. Since an HARQ channel can be setup by two approaches (the end-to-end HARQ mechanism and the hop-by-hop HARQ mechanism), the defects of the HARQ are mainly described from the viewpoints of the two approaches.

Please refer to FIG. 1, which illustrates relay of a data signal by a multi-hop relay (MR) system 1 using a conventional end-to-end HARQ mechanism. The MR system 1 comprises a mobile station (MS), two relay stations (RSs, i.e. RS1 and RS2), and a base station (BS). The BS intends to transmit the data signal to the MS. In FIG. 1, the vertical axes indicate the time, Data* indicates the data signal that is corrupted by noise during transmission, and Data indicates the data signal that is successfully transmitted and not corrupted by noise during transmission. It can be understood that, each of the RSs (i.e. RS1 and RS2) should only relay those successfully received/decoded data signals to its successor by using the end-to-end HARQ mechanism. If the RSs receive an erroneously decoded data signal, it reports a negative-acknowledgement (NACK) to the original sender to indicate the request of retransmission. That is, each of the RSs should relay all received acknowledgement (ACK)/NACK to its predecessor. Furthermore, only a destination of the transmission can initiate an ACK. These actions make too much data transfer latency and decrease the performance of whole system 1. There are other critical issues of the end-to-end HARQ channel. First, in an MR system with centralized scheduling, the pre-schedule bandwidths for multiple links along the relay path may not be fully utilized if there is error occurrence on any link along the relay path. Second, if the HARQ bandwidth allocation is based on on-demand basis, it definitely results in a number of round-trip delays between MS/RS and BS before the data successfully received/decoded at the destination station. Third, the end-to-end HARQ is not suitable for MR system with distributed scheduling.

Please refer to FIG. 2, which illustrates relay of a data signal by an MR system 2 using a conventional hop-by-hop mechanism. The MR system 2 also comprises an MS, two RSs (i.e. RS1 and RS2), and a BS. In FIG. 2, the vertical axes indicate the time, Data* indicates the data signal that is corrupted by noise during transmission, while Data indicates the data signal that is successfully transmitted. By using the hop-by-hop HARQ mechanism, each of the RSs (i.e. RS1 and RS2) should not relay erroneously decoded data signals to its successor unless the data signal is successfully decoded. Furthermore, each of the RSs should not relay received ACK/NACK indications to its predecessor. There are two main defects in a hop-by-hop HARQ mechanism. First, if the relay system 2 adopts centralized scheduling approach, the pre-schedule bandwidths for multiple links along the relay path between BS and MS may not be fully utilized if there is error occurrence on any link along the relay path. Second, if the HARQ bandwidth allocation is based on on-demand manner, it might result in a number of round-trip delays between MS/RS and BS along the relay path.

Accordingly, how to improve the performance of the HARQ in multi-hop relay systems is still an objective for the industry to endeavor.

### SUMMARY OF THE INVENTION

The primary objective of this invention is to provide an apparatus for relaying a data signal in a multi-hop relay network. The apparatus comprises a storage module, a receiving module, and a transmission module. The storage module is configured to store a message of the multi-hop relay network, wherein the message indicates a resource allocation of the multi-hop relay network. The receiving module is configured to receive the data signal. The transmission module is configured to transmit the data signal and a first response signal according to the message in response to the data signal, wherein the first response signal relates to a correctness of the data signal.

Another objective of this invention is to provide a transmission method for relaying a data signal in a multi-hop relay network. The transmission method comprises following steps of: receiving the data signal; transmitting the data signal according to a message of the multi-hop relay network in response to the receiving step, wherein the message indicates a resource allocation of the multi-hop relay network; and transmitting a first response signal according to the message in response to the receiving step, wherein the first response signal relates to a correctness of the data signal.

Yet a further objective of this invention is to provide a tangible machine-readable medium storing a computer program to enable an apparatus to execute a transmission method for relaying a data signal in a multi-hop relay network. The transmission method comprises the steps of: enabling the apparatus to receive the data signal; enabling the apparatus to transmit the data signal according to a message of the multi-hop relay network in response to the receiving step, wherein the message indicates a resource allocation of the multi-hop relay network; and enabling the apparatus to transmit a first response signal according to the message in response to the receiving step, wherein the first response signal relates to a correctness of the data signal.

The present invention provides a new approach to relay a data signal in a multi-hop relay network. In the framework of HARQ, the relay station relays the data signal to successor regardless of the data signal being corrupted by noise or not during transmission. This will effectively utilize the pre-schedule bandwidths for multiple links to improve the performance of the whole relay system in the multi-hop relay network.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic diagram of relay of a data signal by an MR system using a conventional end-to-end HARQ mechanism;

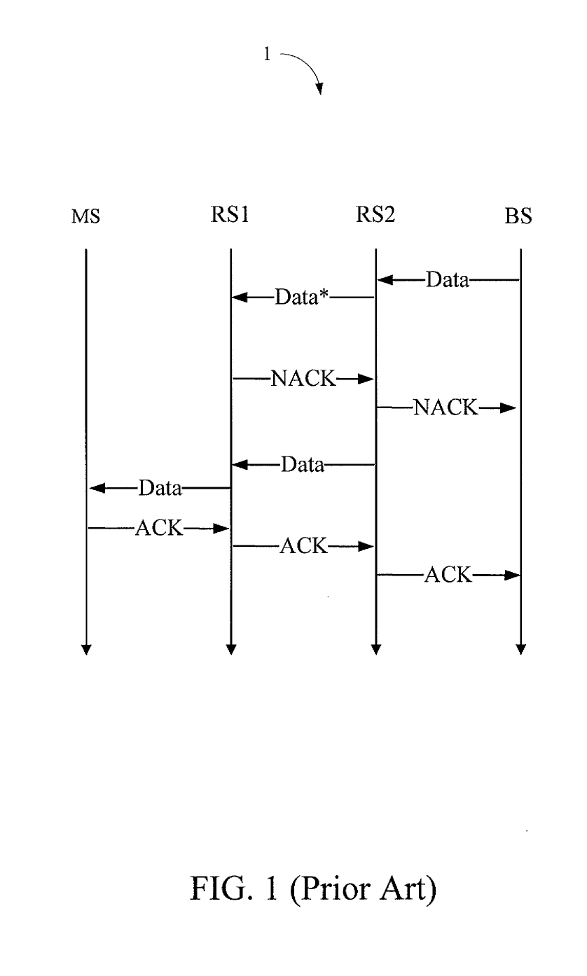

FIG. 2 is a schematic diagram of relay of a data signal by an MR system using a conventional hop-by-hop HARQ mechanism;

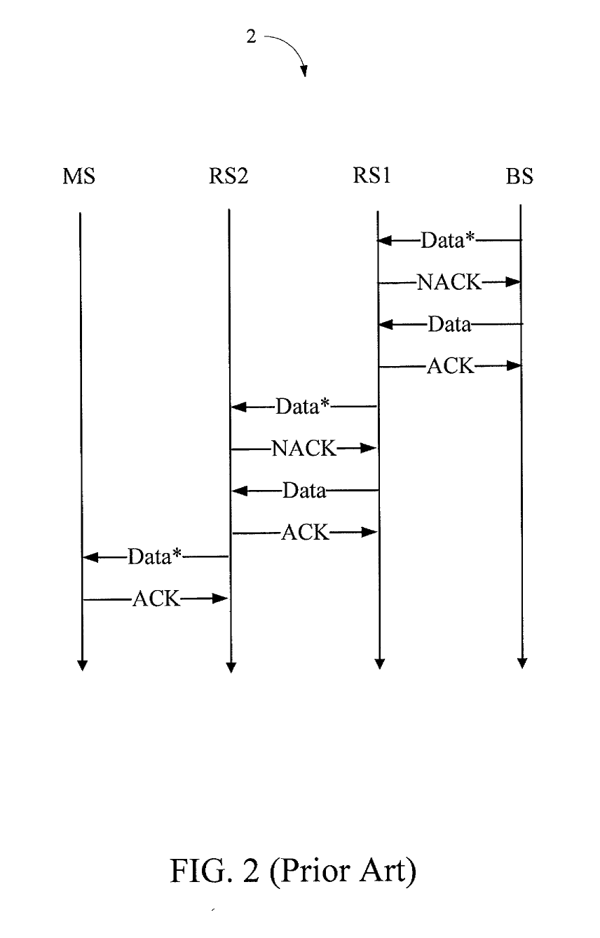

FIG. 3 is a schematic diagram of the first embodiment of the present invention;

FIG. 4 is a schematic diagram of the downlink relay system adopting the apparatus of the first embodiment of the present invention;

FIG. 5A is a partial flow chart of the second embodiment of the present invention; and

FIG. 5B is another partial flow chart of the second embodiment of the present invention.

### DESCRIPTION OF THE PREFERRED EMBODIMENT

The present invention provides an apparatus, a transmission method, and a tangible machine-readable medium thereof for relaying a data signal in a multi-hop relay network. In the following embodiments, multi-hop relay networks based on the IEEE 802.16j standard are used. However, the scope of the present invention is not limited to the applications based on the IEEE 802.16j standard. The relay operations in a multi-hop relay network based on the IEEE 802.16j standard are well-known by people skilled in the art, and are not repeated again. A multi-hop relay network has two kinds of operation: downlink and uplink operations. In this invention, only the downlink operation in the multi-hop relay network is described. It means that only the relay operations from a base station (BS) to a mobile station (MS) are described.

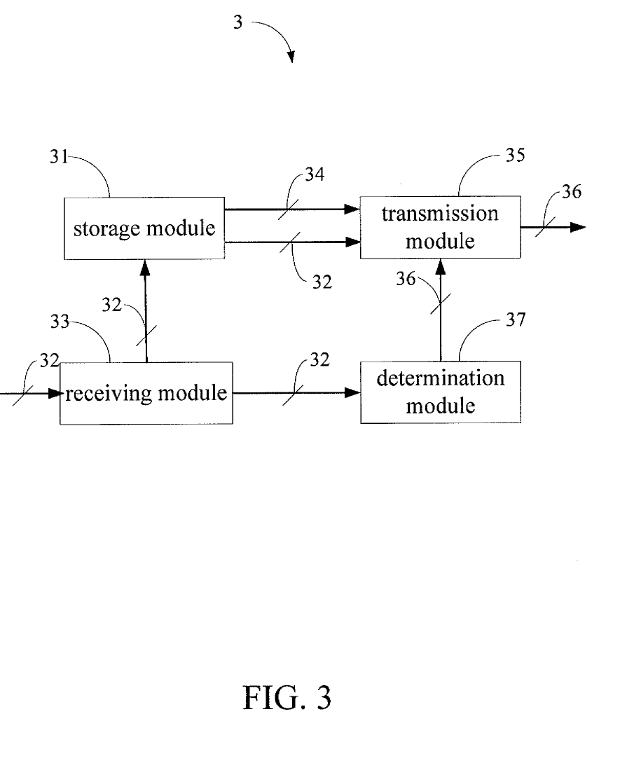

A first embodiment of the present invention is shown in FIG. 3, which illustrates an apparatus 3 for relaying a data signal 32 from a BS to an MS in a multi-hop relay network. The apparatus 3 can serve as a relay station (RS) in the multi-hop relay network. The apparatus 3 comprises a storage module 31, a receiving module 33, a transmission module 35, and a determination module 37. The storage module 31 is configured to store a message 34 of the multi-hop relay network, wherein the message 34 is configured to indicate a resource allocation of the multi-hop relay network.

The receiving module 33 is configured to receive the data signal 32. After the receiving module 33 receives the data signal 32, the storage module 31 will store it. Then, the transmission module 35 is configured to retrieve the data signal 32 from the storage module 31 and transmit the data signal 32 to its successor (to be explained later) and a first response signal 36 to its predecessor (to be explained later) according to the message 34 in response to the data signal 32, wherein the first response signal 36 relates to a correctness of the data signal 32. To be more specific, the data signal 32 is sent to the transmission module 35 and determination module 37 respectively. The determination module 37 is configured to determine whether the data signal 32 is correct or not. That is, the determination module 37 is configured to determine whether the data signal 32 is corrupted by noise during transmission. If the data signal 32 is correct, the determination module 37 is further configured to generate an acknowledgement signal as the first response signal 36 for the transmission module 35 to transmit to its predecessor (to be explained later). If the determination module 37 determines that the data signal is erroneous, a negative-acknowledgement signal is generated as the first response signal 36 for the transmission module 35 to transmit to its predecessor (to be explained later).

The transmission module 35 transmits the aforementioned data signal 32 and the aforementioned first response signal 36 according to the message 34 in response to the data signal 32. Particularly, the message 34 records the relation between the apparatus 3, the BS and the MS. If there are other relay stations in the multi-hop relay network, the message 34 also records the relations between the other relay stations and the apparatus, the BS, and the MS. Consequently, the transmission module 35 of the apparatus 3 can know its successor (such as the RS/MS) and/or predecessor (such as the BS/RS) by the message 34.

In addition, the receiving module 33 is further configured to receive a second response signal intended to be transmitted to the BS. This happens when the data signal 32 finally reaches the MS, and the MS transmits the second response signal to indicate the receiving. The transmission module 35 is further configured to transmit the second response signal according to the message 34. To be more specific, the data signal 32 received by the MS may be correct and may be erroneous. If it is correct, the second response signal is an acknowledgement signal. On the other hand, if the data signal 32 received by the MS is erroneous, the second response signal is a negative-acknowledgement signal. It means that the apparatus 3 can relay an acknowledgement signal and negative-acknowledgement signal in the multi-hop relay network.

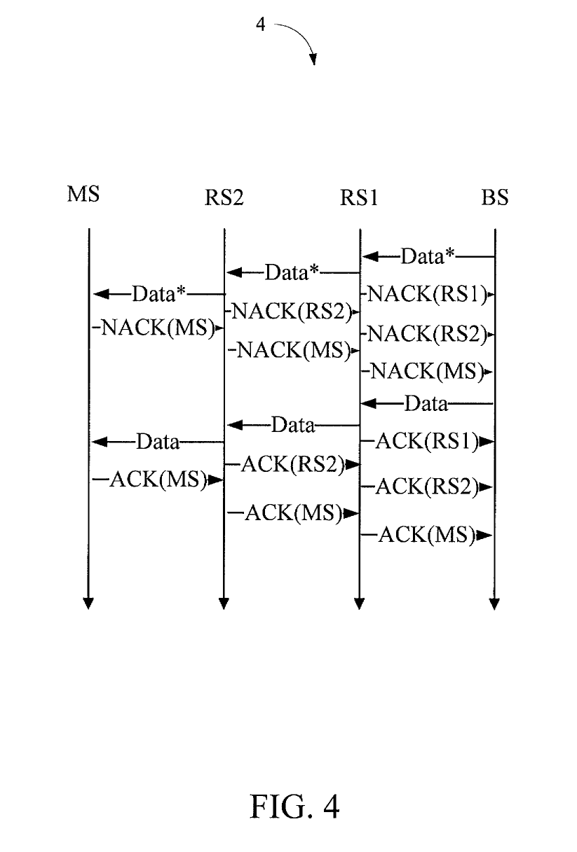

As mentioned, the apparatus 3 can be a relay station in a multi-hop relay system. Please refer to FIG. 4 for a concrete example, which shows a downlink transmission of a data signal in a multi-hop relay system 4. The multi-hop relay system 4 comprises an MS, two RSs (RS1 and RS2), and a BS, wherein each of the RS1 and the RS2 is the apparatus 3 of this embodiment. In addition, in FIG. 4 the vertical axes indicate the time, Data* indicates the data signal that is corrupted by noise during transmission, and Data indicates the data signal that is successfully transmitted.

In the multi-hop relay system 4, each of the RS1 and RS2 (along the routing path from BS to MS) should buffer the data signal sent from its predecessor, forward the data signal to its successor regardless of the correctness of the data signal, report a first response signal to its predecessor in response to the receiving of the data signal, wherein the first response signal may be an acknowledgement signal (ACK) or a negative-acknowledgement signal (NACK). Furthermore, each of the RS1 and RS2 should relay a second response signal that originally comes from the MS to its successor, wherein the second response signal may be an ACK or an NACK.

According to the above configurations, the present invention provides an apparatus to relay a data signal regardless of the correctness of the data signal. This can utilize the pre-schedule bandwidths for multiple links to improve the performance of the downlink relay system in the multi-hop relay network by the apparatus of the invention.

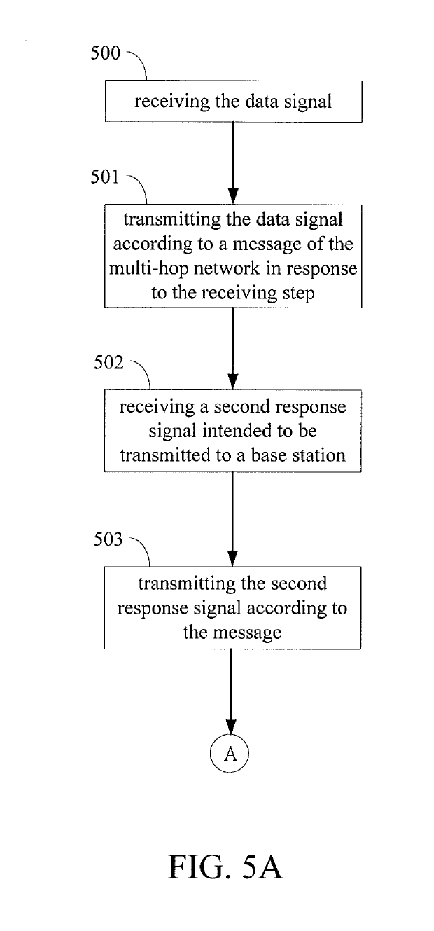

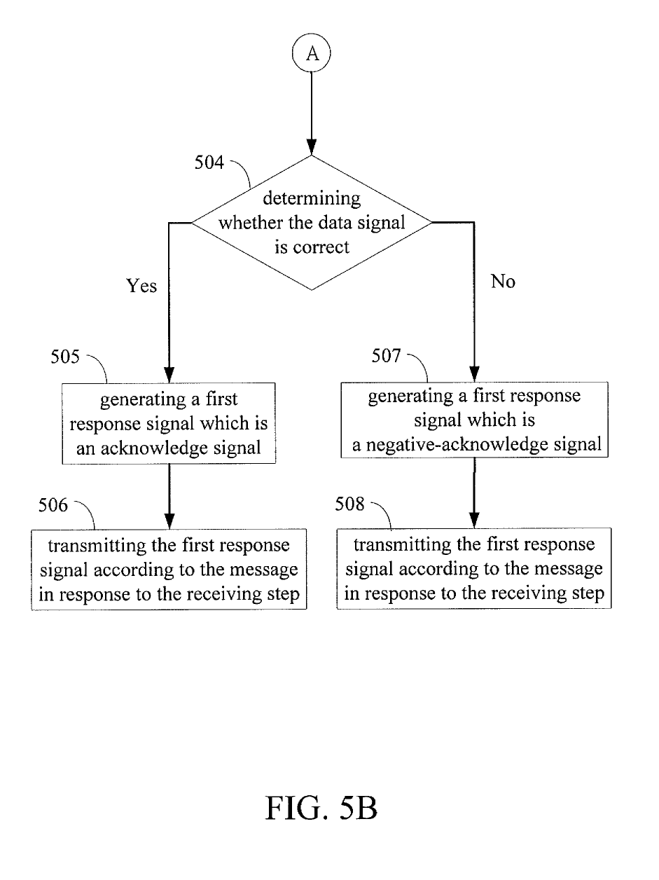

A second embodiment of the present invention is shown in FIG. 5A and 5B, which shows a flow chart of a transmission method for relaying a data signal in a multi-hop relay network, wherein the multi-hop relay network comprising a plurality of relay stations. First, step 500 is executed to receive the data signal. Step 501 is executed to transmit the data signal according to a message of the multi-hop relay network in response to the receiving step 500, wherein the message indicating a relation between the relay stations.

Step 502 is executed to receive a second response signal intended to be transmitted to a base station, wherein the second response signal may be acknowledgement signal or a negative-acknowledgement signal depending on the correctness of the data signal received by a mobile station in the multi-hop relay network. Then, step 503 is executed to transmit the second response signal according to the message. Please refer to FIG. 5B, step 504 is then executed to determine whether the data signal received in the step 500 is correct. If so, step 505 is executed to generate an acknowledgement signal as a first response signal, and then step 506 is executed to transmit the first response signal to a base station in the multi-hop relay network according to the message in response to the receiving step 500.

If it is not in step 504, step 507 is executed to generate a negative-acknowledgement signal as the first response signal, and then step 508 is executed to transmit the first response signal according to the message in response to the receiving step 500.

It is noted that the steps 505, 506 may be executed before the steps 502, 503. Similarly, the steps 507, 508 may be executed before the steps 502, 503. The executing sequence depends on a scheduling algorithm of the BS. In addition to the aforementioned steps, the second embodiment is able to execute all the functions and operations described in the first embodiment.

Each of the aforementioned methods can use a tangible machine-readable medium for storing a computer program to execute the aforementioned steps. The tangible machine-readable medium can be a floppy disk, a hard disk, an optical disc, a flash disk, a tape, a database accessible from a network or a storage medium with the same functionality that can be easily thought by people skilled in the art.

According to the aforementioned descriptions, the present invention provides a new approach to relay a data signal from its predecessor to its successor regardless of the correctness of the data signal. This will effectively utilize the pre-schedule bandwidths to improve the performance of the relay system in the multi-hop relay network. The present invention can be utilized in multi-hop relay network, such as those based on the IEEE 802.16j standard.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. An apparatus for relaying a data signal in a multi-hop relay network, comprising:
a storage module being configured to store a message of the multi-hop relay network, the message indicating a resource allocation of the multi-hop relay network;
a receiving module being configured to receive the data signal;
a transmission module being configured to transmit the data signal and a first response signal according to the message in response to the data signal,
wherein the first response signal relates to a correctness of the data signal.

2. The apparatus of claim 1, further comprising:
a determination module being configured to determine that the data signal is correct,
wherein the first response signal is an acknowledgement signal intended to be transmitted to a base station in the multi-hop relay network.

3. The apparatus of claim 1, further comprising:
a determination module being configured to determine that the data signal is erroneous,
wherein the first response signal is a negative-acknowledgement signal intended to be transmitted to a base station in the multi-hop relay network.

4. The apparatus of claim 1, wherein the receiving module is further configured to receive a second response signal intended to be transmitted to a base station in the multi-hop relay network and the transmission module is further configured to transmit the second response signal according to the message.

5. The apparatus of claim 4, wherein the second response signal is an acknowledgement signal.

6. The apparatus of claim 4, wherein the second response signal is a negative-acknowledgement signal.

7. A transmission method for relaying a data signal in a multi-hop relay network, comprising the steps of:
receiving the data signal;
transmitting the data signal according to a message of the multi-hop relay network in response to the receiving step, the message indicating a resource allocation of the multi-hop relay network; and
transmitting a first response signal according to the message in response to the receiving step,
wherein the first response signal relates to a correctness of the data signal.

8. The transmission method of claim 7, further comprising the step of:
determining that the data signal is correct,
wherein the first response signal is an acknowledgement signal intended to be transmitted to a base station in the multi-hop relay network.

9. The transmission method of claim 7, further comprising the step of:
determining that the data signal is erroneous,
wherein the first response signal is a negative-acknowledgement signal intended to be transmitted to a base station in the multi-hop relay network.

10. The transmission method of claim 7, further comprising the steps of:
receiving a second response signal intended to be transmitted to a base station; and
transmitting the second response signal according to the message.

11. The transmission method of claim 10, wherein the second response signal is an acknowledgement signal.

12. The transmission method of claim 10, wherein the second response signal is a negative-acknowledgement signal.

13. A tangible machine-readable medium storing a computer program to enable an apparatus to execute a transmission method for relaying a data signal in a multi-hop relay network, the transmission method comprising the steps of:
enabling the apparatus to receive the data signal;
enabling the apparatus to transmit the data signal according to a message of the multi-hop relay network in response to the receiving step, the message indicating a resource allocation of the multi-hop relay network; and
enabling the apparatus to transmit a first response signal according to the message in response to the receiving step,
wherein the first response signal relates to a correctness of the data signal.

14. The tangible machine-readable medium of claim 13, wherein the method further comprises the step of:
enabling the apparatus to determine that the data signal is correct,
wherein the first response signal is an acknowledgement signal intended to be transmitted to a base station in the multi-hop relay network.

15. The tangible machine-readable medium of claim 13, wherein the method further comprises the step of
enabling the apparatus to determine that the data signal is erroneous,
wherein the first response signal is a negative-acknowledgement signal intended to be transmitted to a base station in the multi-hop relay network.

16. The tangible machine-readable medium of claim 13, wherein the method further comprises the steps of:
enabling the apparatus to receive a second response signal intended to be transmitted to a base station in the multi-hop relay network; and
enabling the apparatus to transmit the second response signal according to the message.

17. The tangible machine-readable medium of claim 16, wherein the second response signal is an acknowledgement signal.

18. The tangible machine-readable medium of claim 16, wherein the second response signal is a negative-acknowledgement signal.
